(19) United States
(12) Patent Application Publication
(10) Pub. No.: US 2026/0140321 A1
(43) Pub. Date: May 21, 2026

(54) OPTICAL DETECTION CIRCUIT

(71) Applicant: NEC Corporation, Tokyo (JP)

(72) Inventor: Kei IYODA, Tokyo (JP)

(73) Assignee: NEC Corporation, Tokyo (JP)

(21) Appl. No.: 19/385,625

(22) Filed: Nov. 11, 2025

(30) Foreign Application Priority Data
Nov. 20, 2024 (JP) 2024-202207

(51) Int. Cl. G02B 6/293; G02B 6/42

(52) U.S. Cl. CPC G02B 6/2938; G02B 6/29368; G02B 6/29395; G02B 6/4286

(57) ABSTRACT

An optical detection unit detects light incident on first and second light receiving surfaces. An optical waveguide structure splits light incident from a first optical waveguide into first and second split lights and emits the first and second split lights to the first and second light receiving surfaces, and prevents first and second reflected lights generated by reflection of the first and second split lights by the first and second light receiving surfaces from being incident on the first optical waveguide.

### INCORPORATION BY REFERENCE

This application is based upon and claims the benefit of priority from Japanese patent application No. 2024-202207, filed on November 20, 2024, the disclosure of which is incorporated herein in its entirety by reference.

### TECHNICAL FIELD

The present disclosure relates to an optical detection circuit.

### BACKGROUND ART

In an integrated optical circuit fabricated using silicon photonics technology or the like, a large number of waveguide photodiodes (hereinafter, PD) are provided to monitor light intensity in the circuit in order to control operation of the circuit. For example, JP 2020-167359 A proposes an optical circuit that monitors light output from a light source.

### SUMMARY

In a case where the refractive index of the medium is different between the PD and the optical waveguide, reflected light is generated when light enters the PD from the optical waveguide. It is known that in a case where the reflected light from the PD propagates through the optical waveguide in the reverse direction and enters another optical component such as a light source, the operation of the optical integrated circuit is affected. In particular, in the wavelength tunable laser, the reflected light returns to the light source, which causes problems such as instability of laser oscillation and inability of continuous wavelength tunable operation.

A optical detection circuit according to an example aspect includes a first optical waveguide, an optical detection means for detecting light incident on first and second light receiving surfaces; and an optical waveguide means for splitting light incident from a first optical waveguide into first and second split lights and emitting the first and second split lights to the first and second light receiving surfaces, and preventing first and second reflected lights generated by reflection of the first and second split lights by the first and second light receiving surfaces from being incident on the first optical waveguide.

According to an example embodiment, it is possible to provide an optical detection circuit capable of preventing reflected light of light incident through an optical waveguide from entering the optical waveguide.

### BRIEF DESCRIPTION OF DRAWINGS

FIG. 1 is a diagram illustrating a configuration example of a wavelength-tunable light source;

FIG. 2 is a diagram schematically illustrating a configuration of an optical detection circuit according to one example embodiment;

FIG. 3 is a diagram schematically illustrating a configuration of an optical detection circuit according to one example embodiment;

FIG. 4 is a diagram schematically illustrating a configuration example of an optical detection unit according to one example embodiment;

FIG. 5 is a diagram illustrating a reciprocating optical path length of the optical waveguide;

FIG. 6 is a diagram schematically illustrating a configuration of an optical detection circuit according to one example embodiment;

FIG. 7 is a diagram illustrating multiplexing/demultiplexing of light in a 2×2 optical coupler;

FIG. 8 is a diagram schematically illustrating a configuration of an optical detection circuit according to one example embodiment; and

FIG. 9 is a diagram schematically illustrating a configuration of an optical detection circuit according to one example embodiment.

### EXAMPLE EMBODIMENT

Hereinafter, example embodiments of the present invention are described with reference to the diagrams. In the diagrams, the same elements are denoted by the same reference numerals, and repeated description is omitted as necessary.

Hereinafter, the term “one example embodiment” means that it is applicable to any of the example embodiments described below or a combination of two or more example embodiments, and the application is not limited to a specific example embodiment.

### First Example Embodiment

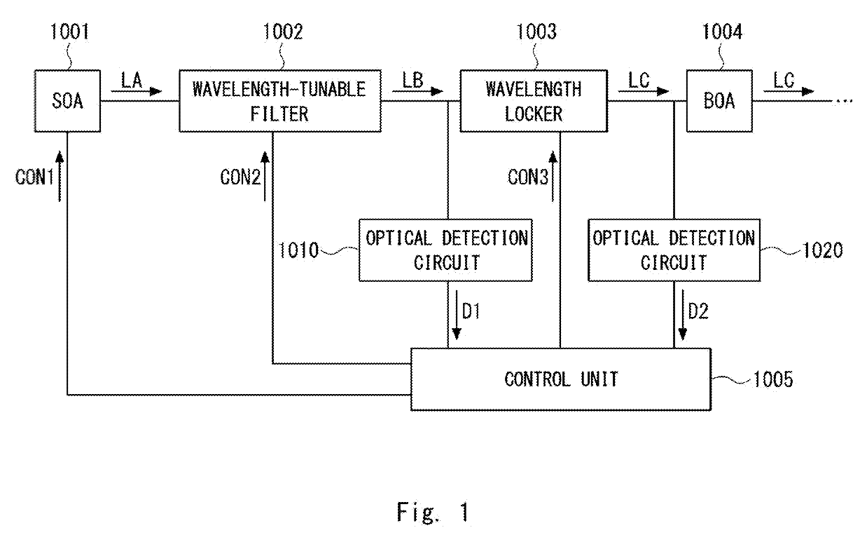

An optical detection circuit according to a first example embodiment will be described. The optical detection circuit is used, for example, for monitoring the intensity of light in various optical circuits. Hereinafter, an example in which the optical detection circuit is used in a wavelength-tunable light source will be described. FIG. 1 is a diagram illustrating a configuration example of a wavelength-tunable light source. A wavelength-tunable light source 1000 includes a semiconductor optical amplifier (hereinafter, SOA) 1001 for laser oscillation, a wavelength-tunable filter 1002, a wavelength locker 1003, a semiconductor amplifier BOA (Booster SOA) 1004 for optical output, and optical detection circuits 1010 and 1020.

In this configuration, the SOA 1001 and the wavelength-tunable filter 1002 constitute a laser resonator. Light LA output from the SOA 1001 reciprocates between the SOA 1001 and the wavelength-tunable filter 1002 to perform laser oscillation, and a laser beam LB having a predetermined wavelength is output. The wavelength locker 1003 outputs a laser beam LC having a fixed wavelength based on the input laser beam LB to the BOA 1004. The BOA 1004 amplifies the laser beam LC and then outputs the laser beam LC. Thus, the wavelength-tunable light source 1000 can supply the laser beam LC having a desired wavelength to another optical device.

At this time, in the wavelength-tunable light source 1000, for example, in order to control the operations of the SOA 1001, the wavelength-tunable filter 1002, and the wavelength locker 1003, it is required to monitor the intensity of the propagating light. In this example, the optical detection circuits 1010 and 1020 detect the laser beam LB from wavelength-tunable filter 1002 and the laser beam LC from the wavelength locker 1003. Then, for example, a control unit 1005 controls the operations of the SOA 1001, the wavelength-tunable filter 1002, and the wavelength locker 1003 by providing control signals CON1 to CON3 according to the detection results D1 and D2 in the optical detection circuits 1010 and 1020.

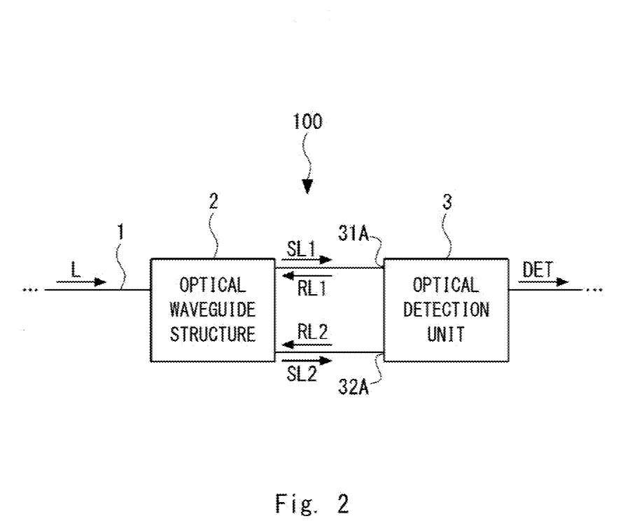

Hereinafter, the optical detection circuit will be described. FIG. 2 is a diagram schematically illustrating a configuration of an optical detection circuit according to one example embodiment. An optical detection circuit 100 of FIG. 2 is used as the above-described optical detection circuits 1010 and 1020. The optical detection circuit 100 includes an optical waveguide 1, an optical waveguide structure 2, and an optical detection unit 3.

The optical waveguide structure 2 is configured as an optical circuit that guides the light L propagating through the optical waveguide 1 to the optical detection unit 3. Hereinafter, the optical waveguide 1 is also referred to as a first optical waveguide. The light L input from the optical waveguide 1 to the optical waveguide structure 2 is split into split light SL1 and SL2 by the optical waveguide 1. Here, it is assumed that the light L is equally divided into the split light SL1 and SL2. However, the splitting ratio of the light L is not limited to 1:1, and may be any splitting ratio. The optical detection unit 3 receives the split light SL1 and SL2 incident on light receiving surfaces 31A and 32A. Then, the optical detection unit 3 outputs a detection signal DET indicating a light reception result. Hereinafter, the split light SL1 and SL2 are also referred to as first and second split light. The light receiving surfaces 31A and 32A are also referred to as first and second light receiving surfaces.

The split light SL1 and SL2 are received by the light receiving surfaces 31A and 32A, but is partially reflected. As a result, the reflected light RL1 and RL2 of the split light SL1 and SL2 return to the optical waveguide structure 2. In a case where the reflected light RL1 and RL2 pass through the optical waveguide structure 2 and propagate through the optical waveguide 1 in the reverse direction, there is a possibility that the operation of other optical components connected to the optical waveguide 1 is adversely affected. In the example of FIG. 1, for example, in a case where the reflected light returns from the optical detection circuit to the wavelength filter or the SOA, a problem such as unstable laser oscillation may occur. Therefore, the optical waveguide structure 2 is configured such that the reflected light RL1 and RL2 do not enter the optical waveguide 1. Hereinafter, the reflected light RL1 and RL2 are also referred to as first and second reflected light.

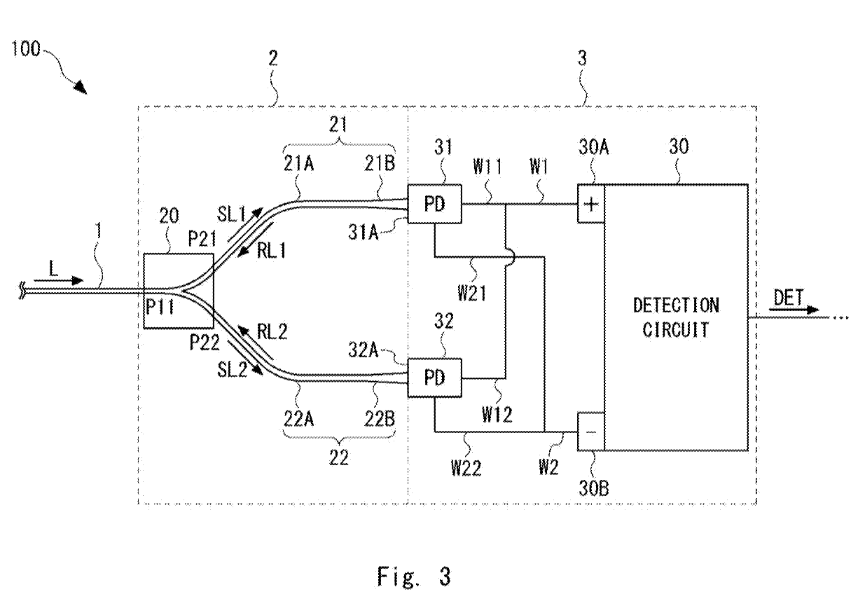

The configuration of the optical detection circuit 100 will be described in more detail. FIG. 3 is a diagram schematically illustrating a configuration of an optical detection circuit according to one example embodiment. The optical waveguide structure 2 includes a 1×2 optical coupler 20 and optical waveguides 21 and 22. An input port P11 of the 1×2 optical coupler 20 is connected to the optical waveguide 1. As a result, the light L enters the input port P11 through the optical waveguide 1. An output port P21 of the 1×2 optical coupler 20 is connected to the optical waveguide 21. An output port P22 of the 1×2 optical coupler 20 is connected to the optical waveguide 22. Hereinafter, the optical waveguides 21 and 22 are also referred to as second and third optical waveguides. Hereinafter, the output ports P21 and P22 are also referred to as first and second output ports.

In the optical waveguide 21, a tapered portion 21B whose width continuously increases toward the optical detection unit 3 is connected to an optical waveguide 21A having a uniform width extending from the output port P21 of the 1×2 optical coupler 20 toward the optical detection unit 3. Similarly, in the optical waveguide 22, a tapered portion 22B whose width continuously increases toward the optical detection unit 3 is connected to an optical waveguide 22A having a uniform width extending from the output port P22 of the 1×2 optical coupler 20 toward the optical detection unit 3.

The 1×2 optical coupler 20 splits the light L into the split light SL1 and the split light SL2. The 1×2 optical coupler 20 emits the split light SL1 from the output port P21 to the optical waveguide 21. The 1×2 optical coupler 20 emits the split light SL2 from the output port P22 to the optical waveguide 22. The split light SL1 and SL2 propagate through the optical waveguides 21 and 22, and are incident on the light receiving surfaces 31A and 32A of the optical detection unit 3.

The optical detection unit 3 includes a detection circuit 30 and photodiodes 31 and 32. Hereinafter, the photodiode is referred to as a PD. As a PD 31 and a PD 32, various PDs such as a PIN (P-intrinsic-N), an avalanche PD, and a waveguide PD may be used.

The PD 31 is connected to the tapered portion 21B of the optical waveguide 21. The split light SL1 enters the light receiving surface 31A of the PD 31 via the optical waveguide 21. The PD 31 converts the split light SL1 incident on the light receiving surface 31A into a current signal. The PD 32 is connected to the tapered portion 22B of the optical waveguide 22. The split light SL2 enters the light receiving surface 32A of the PD 32 via the optical waveguide 22. The PD 32 converts the split light SL2 incident on the light receiving surface 32A into a current signal.

The detection circuit 30 is provided with an anode pad 30A as a positive electrode and a cathode pad 30B as a negative electrode. An anode and a cathode of the PD 31 are connected to wirings W11 and W21. An anode and a cathode of the PD 32 are connected to wirings W12 and W22. Wirings W11 and W12 are connected to the anode pad 30A via a wiring W1. The wirings W12 and W22 are connected to the cathode pad 30B via a wiring W2. As a result, the detection circuit 30 can receive the sum of the current signals output from the PD 31 and the PD 32. The detection circuit 30 adds the received current signals to detect the total intensity of the split light SL1 and SL2, that is, the intensity of the light L. Then, the detection circuit 30 outputs the detection signal DET indicating the intensity of the incident light.

As described above, in the optical detection circuit 100, the light L is divided using the optical coupler 20, but it is possible to receive a current signal having a magnitude similar to that in a case where the light L is received by a general optical detection circuit including one PD. As a result, it is possible to achieve an anti-reflection effect described later in a state where an optical circuit loss similar to that of a general optical detection circuit using one PD is maintained.

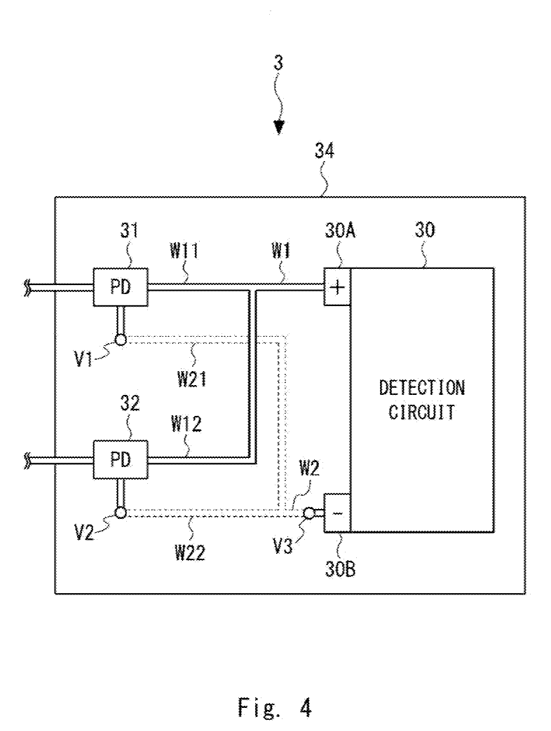

Since the wiring in the optical detection unit 3 is a multilayer wiring, the wiring can be provided while avoiding overlapping. FIG. 4 is a diagram schematically illustrating a configuration example of an optical detection unit according to one example embodiment. As illustrated in FIG. 4, the detection circuit 30, the PDs 31 and 32 are mounted on the main surface of a substrate 34. The wirings W1, W11, and W12 are formed on the main surface of the substrate 34. The wiring W21 is drawn out from the main surface of the substrate 34 to the bottom surface of the substrate 34 via a via V1. The wiring W22 is drawn out from the main surface of the substrate 34 to the bottom surface of the substrate 34 via a via V2. The wirings W21 and W22 on the bottom surface of the substrate 34 are connected to the wiring W2 formed on the bottom surface of the substrate 34. The wiring W2 formed on the bottom surface of the substrate 34 is connected to the cathode pad 30B formed on the main surface of the substrate 34 via a via V3. In FIG. 4, portions of the wirings W2, W21, and W22 formed on the bottom surface of the substrate 34 are indicated by broken lines. Hereinafter, the main surface of the substrate 34 is also referred to as a first surface. A bottom surface opposite to the main surface of the substrate 34 is also referred to as a second surface. The wirings W12 and W21 are also referred to as first and second wirings.

As described above, even in a case where there is an overlapping wiring such as the wiring W12 and the wiring W21 in a plan view of the optical detection unit 3 from the normal direction of the substrate 34, the PDs 31 and 32 and the detection circuit 30 can be efficiently connected without detouring the wiring on the substrate 34 by forming the two intersecting wirings in separate layers.

Next, prevention of the reflected light RL1 and RL2 from entering the optical waveguide 1 by the optical waveguide structure 2 will be described. In the optical detection circuit 100, the split light SL1 guided from the optical waveguide 21 to the PD 31 is reflected by the light receiving surface 31A of the PD 31. As a result, the reflected light RL1 enters the output port P21 of the 1×2 optical coupler 20 through the optical waveguide 21. The split light SL2 guided from the optical waveguide 22 to the PD 32 is reflected by the light receiving surface 32A of the PD 32. As a result, the reflected light RL2 enters the output port P22 of the 1×2 optical coupler 20 through the optical waveguide 22.

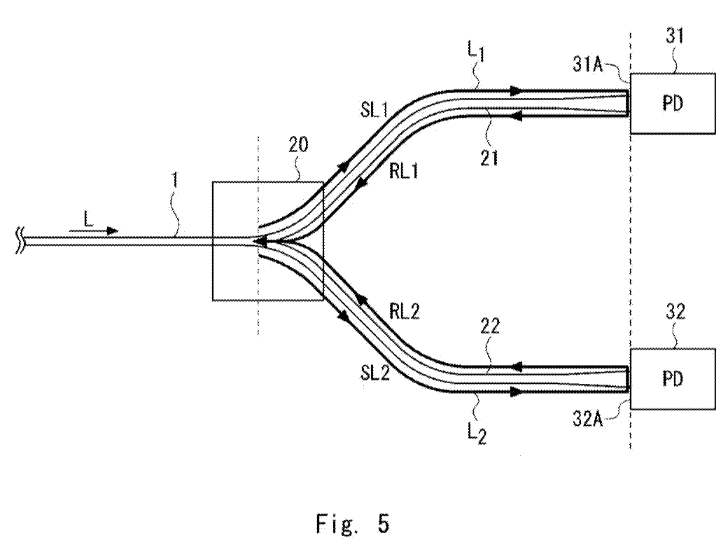

The optical detection circuit 100 is configured such that the phases of the reflected light RL1 and RL2 incident on the 1×2 optical coupler 20 are inverted from each other. Here, the reciprocating optical path lengths in a case where light reciprocates in the optical waveguides 21 and 22 are denoted as L₁ and L₂. FIG. 5 is a diagram illustrating a reciprocating optical path length of the optical waveguide. In the optical waveguide structure 2, the lengths of the optical waveguide 21 and the optical waveguide 22 may be different such that a difference between the reciprocating optical path length L₁ of the optical waveguide 21 and the reciprocating optical path length L₂ of the optical waveguide 22 becomes an optical path length relevant to a phase difference of a half cycle of the light L.

Here, for simplification of description, it is assumed that the difference between the reciprocating optical path length L₁ of the optical waveguide 21 and the reciprocating optical path length L₂ of the optical waveguide 22 is the optical path length relevant to a phase difference of a half cycle of the light L, but the difference between the reciprocating optical path length L₁ and the reciprocating optical path length L₂ is not limited thereto. In a case where n is an integer, the difference between the reciprocating optical path length L₁ and the reciprocating optical path length L₂ may be an optical path length relevant to a value (180° + n × 360°) obtained by adding an optical path length of an integral multiple of a cycle to a phase difference 180° of a half cycle of the light L.

As a result, the phase of the reflected light RL1 incident on the output port P21 of the 1×2 optical coupler 20 and the phase of the reflected light RL2 incident on the output port P22 of the 1×2 optical coupler 20 are inverted from each other. Therefore, in a case where the 1×2 optical coupler 20 combines the reflected light RL1 and the reflected light RL2, the reflected light RL1 and the reflected light RL2 cancel each other out. As a result, the reflected light can be prevented from entering the input port P11 of the 1×2 optical coupler 20.

Although it has been described here that the lengths of the optical waveguide 21 and the optical waveguide 22 are different in order to provide a difference between the reciprocating optical path length L₁ and the reciprocating optical path length L₂, this is merely an example. Other methods may be used as long as a desired difference can be given between the reciprocating optical path length L₁ and the reciprocating optical path length L₂. For example, a difference may be given between the reciprocating optical path length L₁ and the reciprocating optical path length L₂ by adjusting the refractive index by making the waveguide widths of the optical waveguide 21 and the optical waveguide 22 different. In general, the propagation mode of light changes depending on the waveguide width, and the effective refractive index of the optical waveguide changes depending on the propagation mode. Therefore, by making the waveguide widths different, the propagation mode of light reciprocating in the optical waveguide 21 and the propagation mode of light reciprocating in the optical waveguide 22 can be made different. As a result, a phase difference can be given between light reciprocating in the optical waveguide 21 and light reciprocating in the optical waveguide 22. For example, a difference may be given between the reciprocating optical path length L₁ and the reciprocating optical path length L₂ by heating with a heater provided in the optical waveguide 21 and the optical waveguide 22 to adjust the refractive index. A difference may be given between the reciprocating optical path length L₁ and the reciprocating optical path length L₂ by applying a voltage to the electrodes provided in the optical waveguide 21 and the optical waveguide 22 to adjust the refractive index.

Therefore, according to the optical detection circuit 100, it is possible to prevent an adverse effect caused by the reflected light entering another optical component connected to the optical waveguide 1.

For example, in a case where a laser device or a semiconductor optical amplifier is connected to the optical waveguide 1, laser oscillation may be unstable in a case where reflected light enters these devices. On the other hand, according to the optical detection circuit 100, since it is possible to prevent the reflected light from entering the laser device or the semiconductor optical amplifier through the optical waveguide 1, laser oscillation can be maintained in a stable state.

### Second Example Embodiment

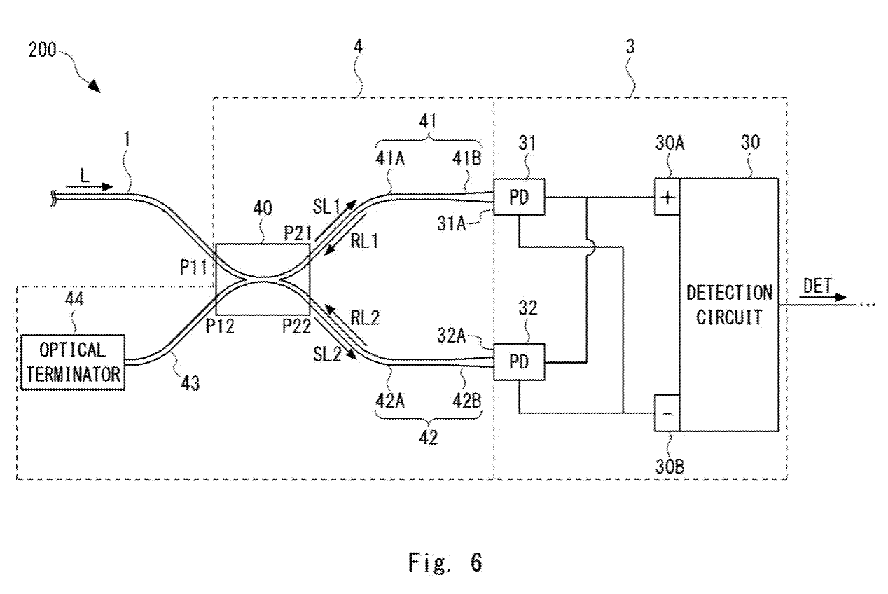

An optical detection circuit according to a second example embodiment will be described. FIG. 6 is a diagram schematically illustrating a configuration of an optical detection circuit according to one example embodiment. An optical detection circuit 200 has a configuration in which the optical waveguide structure 2 in the optical detection circuit 100 is replaced with an optical waveguide structure 4.

Similarly to the optical waveguide structure 2, the optical waveguide structure 4 is configured as an optical circuit that guides the light L propagating through the optical waveguide 1 to the optical detection unit 3. The optical waveguide structure 4 includes a 2×2 optical coupler 40, optical waveguides 41 to 43, and an optical terminator 44.

The 2×2 optical coupler 40 is an optical coupler having two input ports P11 and P12 and two output ports P21 and P22. The input port P11 is connected to the optical waveguide 1. As a result, the light L enters the input port P11 through the optical waveguide 1. The input port P12 is connected to the optical terminator 44 via the optical waveguide 43. The output port P21 and the PD 31 are connected by the optical waveguide 41. The output port P22 and the PD 32 are connected by the optical waveguide 42. Hereinafter, the optical waveguides 41 and 42 are also referred to as second and third optical waveguides, similarly to the optical waveguides 21 and 22. The input ports P11 and P12 are also referred to as first and second input ports.

The optical path lengths of the optical waveguides 41 and 42 are the same, and are configured by an optical waveguide having a uniform width and a tapered portion similarly to the optical waveguides 21 and 22. That is, in the optical waveguide 41, a tapered portion 41B whose width continuously increases toward the PD 31 is connected to an optical waveguide 41A having a uniform width extending from the output port P21 of the 2×2 optical coupler 40 toward the PD 31. In the optical waveguide 42, a tapered portion 42B whose width continuously increases toward the PD 32 is connected to an optical waveguide 42A having a uniform width extending from the output port P22 of the 2×2 optical coupler 40 toward the PD 32.

The 2×2 optical coupler 40 splits the light L into the split light SL1 and the split light SL2. The 2×2 optical coupler 40 emits the split light SL1 from the output port P21 to the optical waveguide 41. The split light SL1 propagates through the optical waveguide 41 and enters the light receiving surface 31A of the PD 31. The 2×2 optical coupler 40 emits the split light SL2 from the output port P22 to the optical waveguide 42. The split light SL2 propagates through the optical waveguide 42 and enters the light receiving surface 32A of the PD 32.

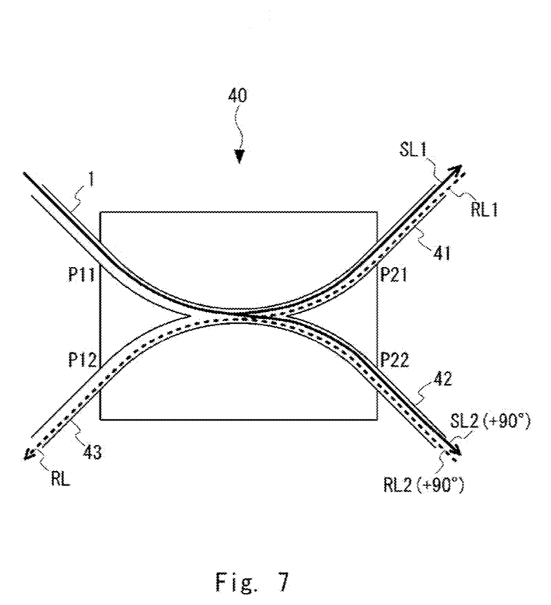

In the optical detection circuit 200, similarly to the optical waveguide structure 2, the optical waveguide structure 4 is configured to prevent incidence of reflected light on the optical waveguide 1. FIG. 7 is a diagram illustrating multiplexing/demultiplexing of light in a 2×2 optical coupler.

The 2×2 optical coupler 40 splits the light L into the split light SL1 and the split light SL2. At this time, the phase of the split light SL2 output from the output port P22 as the cross port is delayed by 1/4 cycle with respect to the split light SL1 output from the output port P21 as the through port.

Thereafter, similarly to the optical waveguide structure 2, the split light SL1 and SL2 are reflected by the light receiving surfaces 31A and 32A to generate the reflected light RL1 and RL2. The reflected light RL1 and RL2 return to the output ports P21 and P22 of the 2×2 optical coupler 40 through the optical waveguides 41 and 42.

The 2×2 optical coupler 40 multiplexes the reflected light RL1 and the reflected light RL2. At this time, the reflected light RL1 and RL2 are demultiplexed to the input ports P11 and P12. The phase of the reflected light RL1 traveling toward the input port P12 is delayed by 1/4 cycle with respect to the phase of the reflected light RL1 traveling toward the input port P11. The phase of the reflected light RL2 traveling toward the input port P11 is delayed by 1/4 cycle with respect to the phase of the reflected light RL2 traveling toward the input port P12.

Therefore, since the phases of the reflected light RL1 and RL2 directed to the input port P11 are inverted, they cancel each other out. As a result, it is possible to prevent the reflected light from entering the optical waveguide 1 from the input port P11.

Similarly, since the phases of the reflected light RL1 and RL2 directed to the input port P12 are delayed by 1/4 cycles, the reflected light RL1 and RL2 intensify each other due to interference. As a result, interference light RL of the reflected light RL1 and RL2 enters the optical waveguide 43 from the input port P12. The interference light RL then enters the optical terminator 44 through the optical waveguide 43. The optical terminator 44 includes, for example, a light absorber, and terminates the incident interference light RL. Hereinafter, the optical waveguides 41 and 42 are also referred to as second and third optical waveguides, similarly to the optical waveguides 21 and 22. The optical waveguide 43 is also referred to as a fourth optical waveguide.

As described above, in the present configuration, by using the multiplexing/demultiplexing characteristics of the 2×2 optical coupler 40, the reflected light RL1 and RL2 can be canceled out by interference, and the reflected light can be prevented from entering the optical waveguide 1.

Since the interference light RL caused by the reflected light RL1 and RL2 emitted from the input port P12 is terminated by the optical terminator 44, it is also possible to prevent an influence on peripheral optical components or the like due to leakage of the interference light RL or the like.

### Third Example Embodiment

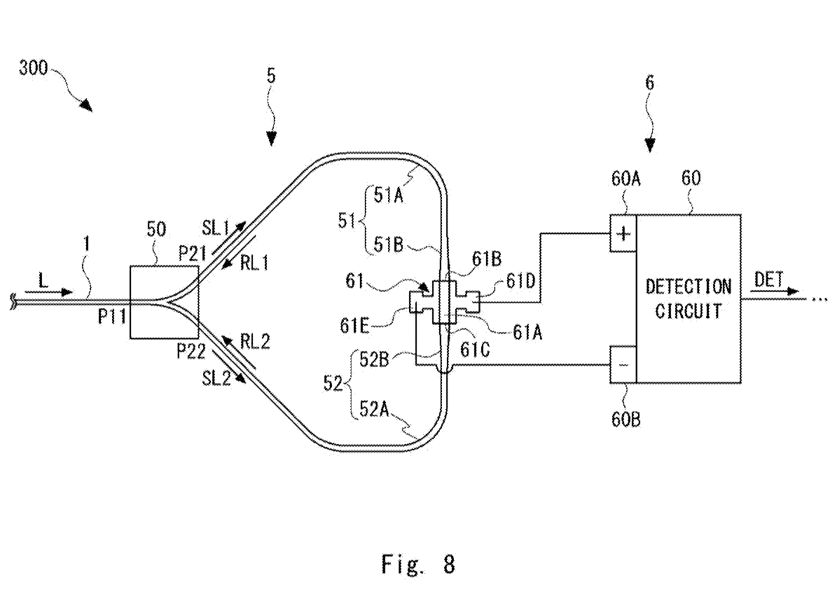

In the above-described example embodiment, the optical detection circuit using two PDs has been described, but it is also possible to configure an optical detection circuit in which the number of PDs is reduced. FIG. 8 is a diagram schematically illustrating a configuration of an optical detection circuit according to one example embodiment. In an optical detection circuit 300, the optical waveguide structure 2 and the optical detection unit 3 in the optical detection circuit 100 are replaced with an optical waveguide structure 5 and an optical detection unit 6.

A 1×2 optical coupler 50 and optical waveguides 51 and 52 of the optical waveguide structure 5 are relevant to the 1×2 optical coupler 20 and the optical waveguides 21 and 22 of the optical waveguide structure 2. An optical waveguide 51A and a tapered portion 51B of the optical waveguide 51 are relevant to the optical waveguide 21A and the tapered portion 21B. An optical waveguide 52A and a tapered portion 52B of the optical waveguide 52 are relevant to the optical waveguide 22A and the tapered portion 22B. Hereinafter, the optical waveguides 51 and 52 are also referred to as second and third optical waveguides, similarly to the optical waveguides 21 and 22.

The optical detection unit 6 includes a detection circuit 60 and a waveguide PD 61. The detection circuit 60 is relevant to the 1×2 optical coupler 50 of the optical waveguide structure 5.

The waveguide PD 61 is configured to be able to detect light incident on an optical waveguide 61A. The split light SL1 enters a light receiving surface 61B, which is an end surface of the optical waveguide 61A, from the tapered portion 51B. The split light SL2 enters a light receiving surface 61C, which is the end surface of the optical waveguide 61A, from the tapered portion 52B. That is, the split light SL1 and SL2 are incident on the optical waveguide 61A from both end surfaces. Therefore, the waveguide PD 61 can be regarded as receiving the light L obtained by adding the split light SL1 and SL2. Hereinafter, the optical waveguide 61A is also referred to as a fifth optical waveguide. The light receiving surfaces 61B and 61C are also referred to as first and second light receiving surfaces, similarly to the light receiving surfaces 31A and 32A.

An anode 61D of the waveguide PD 61 is connected to an anode pad 60A of the detection circuit 60. A cathode pad 61E of the waveguide PD 61 is connected to a cathode pad 60B of the detection circuit 60.

As a result, the detection circuit 60 can receive the current signal output from the waveguide PD 61. The detection circuit 60 detects the intensity of the light L based on the received current signal. Then, the detection circuit 60 outputs a detection signal DET indicating the intensity of the light L.

As described above, the optical detection circuit 300 can similarly detect the light L while reducing the number of PDs as compared with the optical detection circuit 100.

In the optical detection circuit 300, since the optical waveguide structure 5 has the same configuration as the optical waveguide structure 2, it is possible to similarly prevent the reflected light from entering the optical waveguide 1.

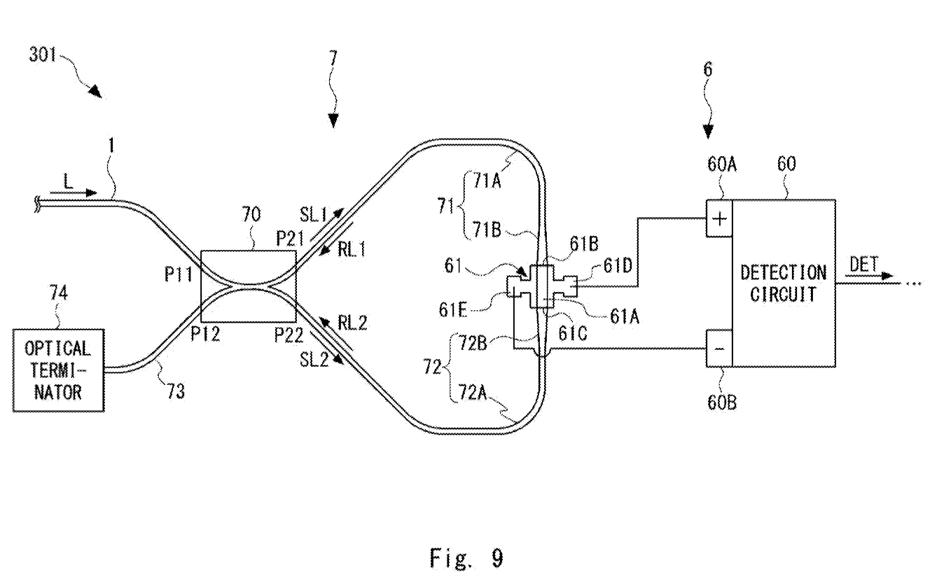

Although the optical detection circuit 300 has been described as a modified example of the optical detection circuit 100, the number of PDs may be reduced in the optical detection circuit 200. FIG. 9 is a diagram schematically illustrating a configuration of an optical detection circuit according to one example embodiment. In an optical detection circuit 301, the optical waveguide structure 4 and the optical detection unit 3 in the optical detection circuit 200 are replaced with an optical waveguide structure 7 and an optical detection unit 6.

A 2×2 optical coupler 70, an optical waveguide 73, and an optical terminator 74 of the optical waveguide structure 7 are relevant to the 2×2 optical coupler 40, the optical waveguide 43, and the optical terminator 44 of the optical waveguide structure 4. Optical waveguides 71 and 72 of the optical waveguide structure 7 are relevant to the optical waveguides 51 and 52 of the optical waveguide structure 5. An optical waveguide 71A and a tapered portion 71B of the optical waveguide 71 are relevant to the optical waveguide 71A and the tapered portion 71B. An optical waveguide 72A and a tapered portion 72B of the optical waveguide 72 are relevant to the optical waveguide 52A and the tapered portion 52B. Hereinafter, the optical waveguides 71 and 72 are also referred to as second and third optical waveguides, similarly to the optical waveguides 21 and 22. The optical waveguide 73 is also referred to as a fourth optical waveguide similarly to the optical waveguide 43.

Since the optical detection unit 6 is similar to the optical detection circuit 300, redundant description will be omitted.

As described above, also in the optical detection circuit 301, the detection circuit 60 can output the detection signal DET indicating the intensity of the light L detected based on the received current signal.

Therefore, the optical detection circuit 301 can similarly detect the light L while reducing the number of PDs as compared with the optical detection circuit 200. In the optical detection circuit 301, since the optical waveguide structure 7 has the same configuration as the optical waveguide structure 4, it is possible to similarly prevent the reflected light from entering the optical waveguide 1.

According to the optical detection circuit in the present example embodiment, since only one PD is used, the influence of the manufacturing error of the PD on the detection of each of the split light SL1 and SL2 can be avoided as compared with the case of using two PDs as in the first and second example embodiments. As a result, according to the optical detection circuit in the present example embodiment, the intensity of the light L can be detected more accurately.

### Other Example Embodiments

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with other embodiments.

In the above-described example embodiment, the multiplexing/demultiplexing means in the optical waveguide structure has been described as an optical coupler, but various multiplexing/demultiplexing means such as a directional coupler may be used as long as similar optical multiplexing/demultiplexing is possible.

In the above-described example embodiment, it has been described that the optical detection circuit is used for a wavelength-tunable light source, but this is merely an example. The optical detection circuit according to the above-described example embodiment may be applied to any optical circuit other than the wavelength-tunable light source.

In the above description, in a case where the optical waveguide and the optical component are described as being connected, it means that the optical waveguide and the optical component are optically connected so that light can be guided between the connected main bodies. Therefore, it does not indicate that the connected entities are in physical contact with each other, and it is not excluded that the components are provided separately as long as light can be guided.

Each of the drawings is merely an example to illustrate one or more example embodiments. Each drawing is not associated with only one specific example embodiment, but may be associated with one or more other example embodiments. As those of ordinary skill in the art will appreciate, various features or steps described with reference to any one of the drawings may be combined with features or steps illustrated in one or more other drawings, for example, to create an example embodiment that is not explicitly illustrated or described. All of the features or the steps illustrated in any one of the drawings for describing illustrative example embodiments are not necessarily mandatory, and some features or steps may be omitted. The order of the steps described in any of the drawings may be changed as appropriate.

Some or all of the above example embodiments can also be described as the following Supplementary Notes, but are not limited to the following.

### (Supplementary Note 1)

An optical detection circuit including:

a first optical waveguide;

an optical detection means for detecting light incident on first and second light receiving surfaces; and

an optical waveguide means for splitting light incident from a first optical waveguide into first and second split lights and emitting the first and second split lights to the first and second light receiving surfaces, and preventing first and second reflected lights generated by reflection of the first and second split lights by the first and second light receiving surfaces from being incident on the first optical waveguide.

### (Supplementary Note 2)

The optical detection circuit according to Supplementary Note 1, in which

the optical waveguide means includes:

an optical multiplexing/demultiplexing means for having an input port and first and second output ports, splitting the light incident on the input port from the first optical waveguide into the first and second split light, and outputting the first and second split light from the first and second output ports;

a second optical waveguide that guides the first split light from the first output port to the first light receiving surface; and

a third optical waveguide that guides the second split light from the second output port to the second light receiving surface,

a difference is provided between an optical path length of the second optical waveguide and an optical path length of the third optical waveguide in such a way that a phase of the second reflected light incident on the second output port from the second light receiving surface through the third optical waveguide is inverted with respect to a phase of the first reflected light incident on the first output port from the first light receiving surface through the second optical waveguide, and

the optical multiplexing/demultiplexing means combines the first reflected light incident on the first output port and the second reflected light having the phase inverted with respect to the phase of the first reflected light incident on the first output port so as to cancel out the first reflected light and the second reflected light each other.

### (Supplementary Note 3)

The optical detection circuit according to Supplementary Note 2, in which the difference between the optical path length of the second optical waveguide and the optical path length of the third optical waveguide is an optical path length relevant to half of a period of the light.

### (Supplementary Note 4)

The optical detection circuit according to Supplementary Note 1, in which

the optical waveguide means includes:

an optical multiplexing/demultiplexing means for having first and second input ports and first and second output ports, splitting the light incident on the first input port from the first optical waveguide into the first and second split lights, outputting the first split light from the first output port, and outputting, from the second output port, the second split light having a phase delayed by 1/4 cycle from a phase of the first split light by the splitting;

a second optical waveguide that guides the first split light from the first output port to the first light receiving surface; and

a third optical waveguide that guides the second split light from the second output port to the second light receiving surface,

the optical multiplexing/demultiplexing means is configured to:

split the first reflected light incident on the first output port from the first light receiving surface through the second optical waveguide toward the first and second input ports; and

split the second reflected light incident on the second output port from the second light receiving surface through the third optical waveguide toward the first and second input ports,

a phase of the first reflected light split toward the second input port is delayed by 1/4 cycle with respect to a phase of the first reflected light split toward the first input port by splitting in the optical multiplexing/demultiplexing means,

a phase of the second reflected light split toward the first input port is delayed by 1/4 cycle with respect to a phase of the second reflected light split toward the second input port by splitting in the optical multiplexing/demultiplexing means; and

canceling out the first and second reflected lights split toward the first input port, which have phases inverted from each other, due to interference.

### (Supplementary Note 5)

The optical detection circuit according to Supplementary Note 4, in which

the optical waveguide means includes:

a fourth optical waveguide connected to the second input port; and

an optical termination means for being connected to the second input port via the fourth optical waveguide,

interference light of the first and second reflected lights split toward the second input port enters the optical termination means through the fourth optical waveguide, and

the optical termination means terminates the interference light.

### (Supplementary Note 6)

The optical detection circuit according to any one of Supplementary Notes 1 to 5, in which the optical detection means includes:

a first light receiving element that outputs a signal indicating a light reception result of the first split light incident on the first light receiving surface;

a second light receiving element that outputs a signal indicating a light reception result of the second split light incident on the second light receiving surface; and

a detection means for adding the signal output from the first light receiving element and the signal output from the second light receiving element to detect the light.

### (Supplementary Note 7)

The optical detection circuit according to Supplementary Note 6, in which

the first and second light receiving elements and the detection means are provided on a first surface of a substrate,

a plurality of wirings connecting the first and second light receiving elements and the detection means include first and second wirings, and

a part or all of the first wiring is provided on the first surface, and a part or all of the second wiring is provided on a second surface opposite to the first surface of the substrate so as to separate, in a normal direction, a portion of the first wiring and a portion of the second wiring overlapping each other in a case where the substrate is viewed from the normal direction of the first surface.

### (Supplementary Note 8)

The optical detection circuit according to any one of Supplementary Notes 1 to 5, in which the optical detection means includes:

a waveguide photodiode that has a fifth optical waveguide whose end surfaces on both sides are the first and second light receiving surfaces, and outputs a signal indicating a light reception result of the first and second split lights incident on the fifth optical waveguide via the first and second light receiving surfaces; and

a detection means for adding and detecting the first and second split lights based on the signal output from the waveguide photodiode.

1. An optical detection circuit comprising:
a first optical waveguide;
an optical detector configured to detect light incident on first and second light receiving surfaces; and
an optical waveguide structure configured to split light incident from a first optical waveguide into first and second split lights, to emit the first and second split lights to the first and second light receiving surfaces, and to prevent first and second reflected lights generated by reflection of the first and second split lights by the first and second light receiving surfaces from being incident on the first optical waveguide.

2. The optical detection circuit according to claim 1, wherein
the optical waveguide structure comprises:
an optical multiplexer/demultiplexer having an input port and first and second output ports configured to split the light incident on the input port from the first optical waveguide into the first and second split lights, and to output the first and second split lights from the first and second output ports;
a second optical waveguide configured to guide the first split light from the first output port to the first light receiving surface; and
a third optical waveguide configured to guide the second split light from the second output port to the second light receiving surface,
a difference is provided between an optical path length of the second optical waveguide and an optical path length of the third optical waveguide in such a way that a phase of the second reflected light incident on the second output port from the second light receiving surface through the third optical waveguide is inverted with respect to a phase of the first reflected light incident on the first output port from the first light receiving surface through the second optical waveguide, and
the optical multiplexer/demultiplexer combines the first reflected light incident on the first output port and the second reflected light having the phase inverted with respect to the phase of the first reflected light incident on the first output port so as to cancel out the first reflected light and the second reflected light each other.

3. The optical detection circuit according to claim 2, wherein the difference between the optical path length of the second optical waveguide and the optical path length of the third optical waveguide is an optical path length relevant to half of a period of the light.

4. The optical detection circuit according to claim 1, wherein
the optical waveguide structure comprises:
an optical multiplexer/demultiplexer having first and second input ports and first and second output ports configured to split the light incident on the first input port from the first optical waveguide into the first and second split lights, to output the first split light from the first output port, and to output, from the second output port, the second split light having a phase delayed by 1/4 cycle from a phase of the first split light by the splitting;
a second optical waveguide configured to guide the first split light from the first output port to the first light receiving surface; and
a third optical waveguide configured to the second split light from the second output port to the second light receiving surface,
the optical multiplexer/demultiplexer is configured to:
split the first reflected light incident on the first output port from the first light receiving surface through the second optical waveguide toward the first and second input ports; and
split the second reflected light incident on the second output port from the second light receiving surface through the third optical waveguide toward the first and second input ports,
a phase of the first reflected light split toward the second input port is delayed by 1/4 cycle with respect to a phase of the first reflected light split toward the first input port due by splitting in the optical multiplexer/demultiplexer,
a phase of the second reflected light split toward the first input port is delayed by 1/4 cycle with respect to a phase of the second reflected light split toward the second input port by splitting in the optical multiplexer/demultiplexer, and
canceling out the first and second reflected lights split toward the first input port, which have phases inverted from each other, due to interference.

5. The optical detection circuit according to claim 4, wherein
the optical waveguide structure comprises:
a fourth optical waveguide connected to the second input port; and
an optical terminator connected to the second input port via the fourth optical waveguide,
interference light of the first and second reflected lights split toward the second input port enters the optical terminator through the fourth optical waveguide, and
the optical terminator terminates the interference light.

6. The optical detection circuit according to claim 1, wherein
the optical detector comprises:
a first light receiving element configured to output a signal indicating a light reception result of the first split light incident on the first light receiving surface;
a second light receiving element configured to output a signal indicating a light reception result of the second split light incident on the second light receiving surface; and
a detector configured to add the signal output from the first light receiving element and the signal output from the second light receiving element to detect the light.

7. The optical detection circuit according to claim 6, wherein
the first and second light receiving elements and the detector are provided on a first surface of a substrate,
a plurality of wirings connecting the first and second light receiving elements and the detector include first and second wirings, and
a part or all of the first wiring is provided on the first surface, and a part or all of the second wiring is provided on a second surface opposite to the first surface of the substrate so as to separate, in a normal direction, a portion of the first wiring and a portion of the second wiring overlapping each other in a case where the substrate is viewed from the normal direction of the first surface.

8. The optical detection circuit according to claim 1, wherein
the optical detector comprises:
a waveguide photodiode that has a fifth optical waveguide whose end surfaces on both sides are the first and second light receiving surfaces, and outputs a signal indicating a light reception result of the first and second split lights incident on the fifth optical waveguide via the first and second light receiving surfaces; and
a detector configured to add and detect the first and second split lights based on the signal output from the waveguide photodiode.
